(19) United States
(12) Patent Application Publication
(10) Pub. No.: US 2002/0014406 A1
(43) Pub. Date: Feb. 7, 2002

(54) ALUMINUM TARGET MATERIAL FOR SPUTTERING AND METHOD FOR PRODUCING SAME

(76) Inventor: HIROSHI TAKASHIMA, SHIMANE-KEN (JP)

Correspondence Address: SUGHRUE MION ZINN MACPEAK AND SEAS, 2100 PENNSYLVANIA AVENUE N W, WASHINGTON, DC, 200373202

(21) Appl. No.: 09/081,994

(22) Filed: May 21, 1998

(51) Int. Cl. C23C 14/34; C22C 21/00

(52) U.S. Cl. 204/298.13; 204/298.12; 148/688; 148/695; 148/415; 148/418; 148/437; 420/528; 420/550; 420/552; 419/28; 148/551; 204/192.15; 204/192.17

(57) ABSTRACT

The first Al-based target material for sputtering contains 0.01-10 atomic % of at least one intermetallic compound-forming element, and an intermetallic compound having a maximum diameter of substantially 50 μm or less. The second Al-based target material for sputtering has a microstructure comprising an alloy phase containing 20 atomic % or less of the intermetallic compound-forming element and Al and an Al matrix phase comprising substantially pure Al, the maximum diameter of the intermetallic compound in the alloy phase being substantially 50 μm or less. The content of the intermetallic compound forming element based on the whole structure is 0.01-10 atomic %. These target materials are produced by pressure-sintering a rapid solidification powder at 400-600° C. After the pressure sintering, the target material is preferably hot-rolled at 400-600° C.

### FIELD OF THE INVENTION

The present invention relates to an aluminum-based target material for sputtering used in forming thin-film electrodes, thin-film interconnections, etc. for a liquid crystal display (hereinafter referred to as LCD), and a production method thereof.

### DESCRIPTION OF THE RELATED ART

Thin films of a high melting metal such as Cr, Ta, Ti, etc. or its alloy have been conventionally used as interconnections, electrodes, etc. of LCD, thin-film sensor, etc. comprising a glass substrate and thin-film devices formed thereon. Recent demands for LCD of larger size and higher resolution require to reduce the resistivity, relieve the stress and stabilize the characteristics of the thin-film interconnections and electrodes to avoid the delay of signals.

For example, a specific resistivity of 15 μΩ·cm or less is required for the electrode used in a large color LCD of 12-inch large or more. However, the thin films of the high melting metals such as Cr, Ta, Ti, etc. do not meet this requirement due to their high resistivity.

For example, the specific resistivity of the thin film is about 30 μΩ·cm for Cr, about 180 μΩ·cm for Ta and about 60 μΩ·cm for Ti. Therefore, to achieve a thin film having a resistivity lower than that of the high melting metals, thin films of aluminum have been proposed.

LCD of larger size and higher resolution further requires to increase the size of a target material used for forming thin films of metal on an LCD substrate. In a sputtering system for stably forming thin films of metal with high quality, a single substrate system where a thin film is formed on a stationary substrate is gradually replacing the conventional large inline system where a thin film is formed on a substrate being transferred. In the single substrate system, the target material is required to be larger than the substrate. Therefore, a target material of the required size has been obtained by combining two or three target pieces. However, during the sputtering process of such a combined target material, dust particles generate from the seams between the target pieces to result in defective thin films. Therefore, a target material of integral body has been demanded. In addition, since the LCD substrate coming to be mainly used has a size of 370 mm×470 mm or larger, a target material use in the single substrate sputtering system for forming a thin film of metal on the LCD substrate is required to have a sputtering surface of 550 mm×650 mm or wider.

A target material of integral body having a large sputtering surface is produced by plastic working such as rolling, etc. Al alloys provide a large target material of integral body more easily as compared with the high melting metals such as Cr, Ta, etc. due to their good cold or hot plastic workability. Therefore, various large target materials made of Al alloys have been proposed. One of simple methods of producing the Al-based target material is a combination of casting and rolling. In this method, an Al alloy is cast into an ingot, which is then cold or hot-rolled after optional machining, and finally the rolled product is finished to obtain a target material. For example, a large target material of integral body having a size of 550 mm×650 mm or larger is produced by subjecting an ingot with increased size to a cold or hot plastic working under a high rolling reduction of about 80% or more.

Various improvements have been made with respect to the composition of the target material. For example, a heat treatment at about 250-400° C., etc. after forming thin-film electrodes is essential to produce an aluminum thin-film transistor (TFT). Since a thin film of pure Al has a low resistivity, but a poor heat resistance, during such a heat treatment, minutes protrusions, called hillocks, are formed on the surface. Although the mechanism of the hillock formation has not yet been satisfactorily elucidated, it may be attributed to stress migration, thermal migration, etc. The hillock formation causes several problems such as a short circuit in Al thin-film interconnections and thin-film electrodes, and a corrosion of the Al thin-film interconnections and thin-film electrodes due to etching solutions penetrated through the holes made in an insulating layer, a protective layer, etc. due to hillock growth.

Therefore, in place of using pure Al as the target material, aluminum alloyed with a small amount of a high melting metal or a rare earth metal has been proposed as an alternative material.

For example, a target material obtained by casting an Al alloy containing 1 weight % of Sm, and machining the cast product after hot-rolling is disclosed in A. Joshi, et al., “Aluminum-samarium alloy for interconnections in integrated circuits”, J. Vac. Sci. Techno. A, Vol. 8, No. 3, May/June 1990, pp1480-1483. The thin film of the Al alloy formed by sputtering the target material contains SmAl₃ precipitates which are 0.3-0.5 μm in diameter and are 5-10 μm apart from each other. This reference teaches that the thin film of the Al alloy has a high electrical conductivity due to a low solid solubility of Sm in Al, and exhibits a low hillock growth propensity comparable to those of Al—Si, Al—Ti, and Al—Cu—Si alloys.

Japanese Patent Laid-Open No. 4-323872 discloses a sputtering target made of an Al cast alloy containing 0.05-1.0 atomic % of at least one of Mn, Zr and Cr. Japanese Patent Publication No. 4-48854 discloses a sputtering target made of an Al cast alloy containing 0.002-0.5 weight % of B and 0.002-0.7 weight % of one or more of Hf, Nb, Ta, Mo and W.

WO 92/13360 discloses a sputtering target for forming an aluminum alloy wiring layer, containing 0.01-1.0 weight % of scandium, or 0.01-1.0 weight % of scandium and 0.01-3.0 weight % of at least one element selected from the group consisting of silicon, titanium, copper, boron, hafnium and rare earth elements excluding scandium, and the balance being aluminum with a purity of 99.99% or more. The sputtering target with a uniform fine crystal structure is obtained by a series of steps of adding at least one additive element to a high purity aluminum, melting, casting, heat-treating, rolling and reheating.

Japanese Patent Laid-Open No. 5-65631 discloses a sputtering target made of an Al alloy containing one or more of Ti, Zr and Ta in a total amount of 0.2-10 atomic %. The sputtering target is produced by a casting method.

Japanese Patent Laid-Open No. 5-335271 discloses a target comprising an AlSi alloy containing 0.01-3 weight % of one or more elements selected from Cu, Ti, Pd, Zr, Hf, Y and Sc. The Al alloy having the above composition is produced by a casting method. The cast Al alloy is then heated at 500-650° C. for at least 30 minutes, rapidly cooled to room temperature within 10 minutes, rolled into a target form, and reheated at 100-500° C. for 5-30 minutes to obtain the target. In the cast Al alloy target, intermetallic compounds of the above additive elements with Al are dispersed in the Al matrix. Although the intermetallic compounds are likely to segregate because the specific gravity thereof is different from that of Al, it is taught that a fine and uniform structure can be achieved by the above heat treatment.

Japanese Patent Laid-Open No. 6-299354 discloses a sputtering target made of an Al alloy in which a rare earth element or a transition metal element is dissolved into Al in nonequilibrium state in an amount of the solid solubility limit or more. The sputtering target is (i) a composite target comprising a target substrate of pure Al having thereon 5 mm-square chips of a rare earth element or a transition metal element of Groups IIIa to VIII, or (ii) a cast Al alloy target containing rare earth element or transition metal element.

Japanese Patent Laid-Open No. 6-336673 discloses a sputtering target for forming wiring, comprising 0.2-6.0 weight % of one or more of Group 4A or 5A metal elements excluding titanium, 0.2-6.0 weight % (30 weight % or more of a total amount of Group 4A or 5A metal elements) of titanium, and the balance being substantially aluminum. The segregation of intermetallic compounds is avoided by increasing the content of titanium to 30 weight % or more. The target is made by casting an Al alloy melt having the above composition into an ingot by a bottom pouring method and rolling the ingot.

Japanese Patent Laid-Open No. 7-45555 discloses a sputtering target for forming electrode films for semiconductor devices, which is made of an Al alloy containing 0.1-10 atomic % in total of one or more elements selected from Fe, Co, Ni, Ru, Rh and Ir, or containing 0.05-15 atomic % in total of one or more rare earth elements. A sputter-deposited thin film of the Al alloy is heat-treated at 150-400° C. to precipitate intermetallic compounds. The target is (i) a composite target comprising a substrate of pure Al having thereon 5 mm-square chips of Fe, Co, Ni, Ru, Rh or Ir, or chips of rare earth elements, or (ii) a cast Al alloy target containing Fe, etc. or rare earth elements.

In the conventional techniques mentioned above, the effort was directed to the choice of the additive elements to eliminate the hillock formation or the modification of the casting method to prevent the intermetallic compounds from segregating. For example, the macroscopic segregation of the intermetallic compounds of Al with the additive elements in an ingot can be prevented by cooling the cast ingot as rapidly as possible. However, the microscopic segregation in the cast ingot cannot be avoided because flaky intermetallic compounds therein aggregate together. Therefore, a target material made by a casting method is not suitable for forming thin films serving as fine interconnections of LCD.

An alternative method of preventing the macroscopic segregation in a target material may be a sintering of a starting powder mixture. It has been confirmed that the degree of segregation increases with increasing particle size of the starting powder material, when a mixture of pure Al and the additive elements is used as the starting material. Therefore, a fine powder is desired to be used as the starting material to decrease the degree of segregation. However, handling of fine Al powder and fine powders of the additive elements necessitates extreme care, because they are liable to be oxidized or ignite. In addition, such powders are likely to aggregate together during a blending process. Therefore, it is difficult to obtain a target material with a satisfactorily uniform and fine structure by sintering a powder mixture of pure Al and the additive elements. Another alternative method may include to blend a pure Al powder with a powder of the intermetallic compounds of the additive elements with Al. However, there is a limit in refining the intermetallic compounds. When a target material contains coarse intermetallic compounds, the concentration of the additive elements in the thin film of Al alloy being formed varies with the sputtering time due to the difference in the sputtering efficiency between Al and the intermetallic compounds.

In addition, when a large target material made of a cast Al alloy is sputtered, unusual splash may generate from the target material. Since the splash is much larger than the sputtered particles in size, the splash attached to the surface of LCD substrate causes a short circuit between interconnections. Since the splash generation extremely decreases the yield of LCD production, it is very important for the production of a large LCD to prevent the splash generation.

As a result of intense study, the inventors have found that minute voids in a target material may be attributed to the splash generation. The minute voids may include (i) shrinkage cavities occurred during casting a large ingot due to a large thermal contraction of Al, and (ii) minute voids formed at the time of solidification of an Al melt by liberating hydrogen dissolved in the Al melt. In particular, the minute voids are likely to form in an ingot when the ingot is solidified by rapid cooling to prevent the intermetallic compounds from segregating. In addition, the intermetallic compounds of the additive elements with Al present in an ingot are fractured during rolling the ingot, this also forming minute voids.

As a result of intense study on preventing the minute void formation in a target material, the inventors have further found that the void formation due to the shrinkage cavity and the dissolved hydrogen cannot be prevented as long as the target material is produced by a casting method. The powder sintering method can avoid the void formation due to the shrinkage cavity and the dissolved hydrogen. However, it has been also found that the voids may be formed in a target material produced by sintering a powder mixture of the additive elements and Al due to the fracture, during rolling, of coarse flaky intermetallic compounds formed by the reaction between the additive elements and Al.

### OBJECT OF THE INVENTION

Accordingly, an object of the present invention is to provide an Al-based target material for sputtering containing finely divided intermetallic compounds and having a microstructure with a minimized amount of minute voids which cause a splash generation, thereby enabling the deposition of uniform thin films of an Al alloy having a low resistivity with little splash.

Another object of the present invention is to provide a method of producing such an Al-based target material for sputtering.

### SUMMARY OF THE INVENTION

As a result of the intense research in view of the above objects, the inventors have found that a sintered body having a microstructure in which finely divided intermetallic compounds are uniformly dispersed can be obtained by pressure-sintering an Al alloy powder, with or without Al powder, which is produced by rapidly solidifying an Al alloy melt added with a hillock growth-preventing element, because the growth of the intermetallic compounds to flaky shape is prevented. The inventors have further found that a target material having a uniform and fine structure can be obtained by rolling the above sintered body without causing the fracture of the intermetallic compounds, and that such a target material provides thin films of the Al alloy with minimized variation in the concentration of the additive element without causing the splash generation during the sputtering of the target material.

Thus, a first Al-based target material for sputtering of the present invention is characterized by containing at least one intermetallic compound-forming element and an intermetallic compound having a maximum diameter of substantially 50 μm or less.

A second Al-based target material for sputtering of the present invention is characterized by having a microstructure comprising an alloy phase containing an intermetallic compound-forming element and Al and an Al matrix phase, and characterized by an intermetallic compound in the alloy phase having a maximum diameter of substantially 50 μm or less.

A first method of producing the Al-based target material for sputtering of the present invention is characterized by comprising the steps of preparing an alloy powder by rapidly solidifying an alloy melt comprising 0.01-10 atomic %, preferably 0.01-5 atomic % of an intermetallic compound-forming element and a balance being substantially Al; and pressure-sintering the alloy powder at 400-600° C. It is preferable to hot-roll the target material after the pressure sintering.

A second method of producing the Al-based target material for sputtering of the present invention is characterized by comprising the steps of mixing a rapid solidification powder of an Al alloy comprising an intermetallic compound-forming element and Al with a powder of pure Al; and pressure-sintering the powder mixture at 400-600° C. The content of the intermetallic compound-forming element is 0.01-10 atomic %, preferably 0.01-5 atomic %. Like the first method, it is preferable to hot-roll the target material after the pressure sintering.

### BRIEF DESCRIPTION OF THE DRAWINGS

FIG. 1 is a schematic illustration showing the microstructure of a first target material of the present invention;

FIG. 2 is a schematic illustration showing an intermetallic compound in the microstructure of a first target material of the present invention;

FIG. 3 is a schematic illustration showing the microstructure of a second target material of the present invention;

FIG. 4 is a schematic illustration showing an intermetallic compound in the alloy phase of a second target material of the present invention;

FIG. 5 is a photomicrograph (×400) showing the microstructure of the sintered, non-rolled, single-phase target material of Example 10;

FIG. 6 is a photomicrograph (×400) showing the microstructure of the cast, non-rolled, single-phase target material of Comparative Example 3;

FIG. 7 is a photomicrograph (×400) showing the microstructure of the sintered, rolled, single-phase target material of Example 20;

FIG. 8 is a photomicrograph (×400) showing the microstructure of the cast, rolled, single-phase target material of Comparative Example 10;

FIG. 9 is a photomicrograph (×100) showing the microstructure of the sintered, non-rolled, composite-phase target material of Example 21; and

FIG. 10 is a photomicrograph (×100) showing the microstructure of the sintered, rolled, composite-phase target material of Example 26.

### DESCRIPTION OF PREFERRED EMBODIMENTS

[A] Target Material

[1] First Target Material

(1) Composition

The first target material comprises an Al alloy containing at least one intermetallic compound-forming element. The intermetallic compound-forming element may include (i) Group 2A elements such as Mg, etc., (ii) Group 3A elements commonly referred to as rare earth elements including Sc, Y and lanthanoids, (iii) Group 4A elements such as Ti, Zr and Hf, (iv) Group 5A elements such as V, Nb and Ta, (v) Group 6A elements such as Cr, Mo and W, (vi) Group 7A elements such as Mn, Tc and Re, (vii) Group 8 elements such as Fe, Co, Ni, Ru, Rh, Pd, Os, Ir and Pt, and (viii) Group 1B elements such as Cu, Ag and Au. Of the above additive elements, preferred are rare earth elements (Group 3A). Among the transition elements, at least one rare earth element is preferably used.

The Al alloy is preferred to comprise 0.01-10 atomic % of the intermetallic compound-forming element (additive element), and the balance being substantially Al. When the amount of the additive element exceeds 10 atomic %, the void formation during pressure sintering and rolling may occur because an excessively large amount of intermetallic compound is formed. When the content of the additive element is less than 0.01 atomic %, only a little amount of the intermetallic compound is formed, thereby failing to prevent the hillock formation. A preferred content of the additive element depends on the element being used, and usually 0.01-5 atomic %. A more preferred content is 0.01-1 atomic %.

(2) Microstructure

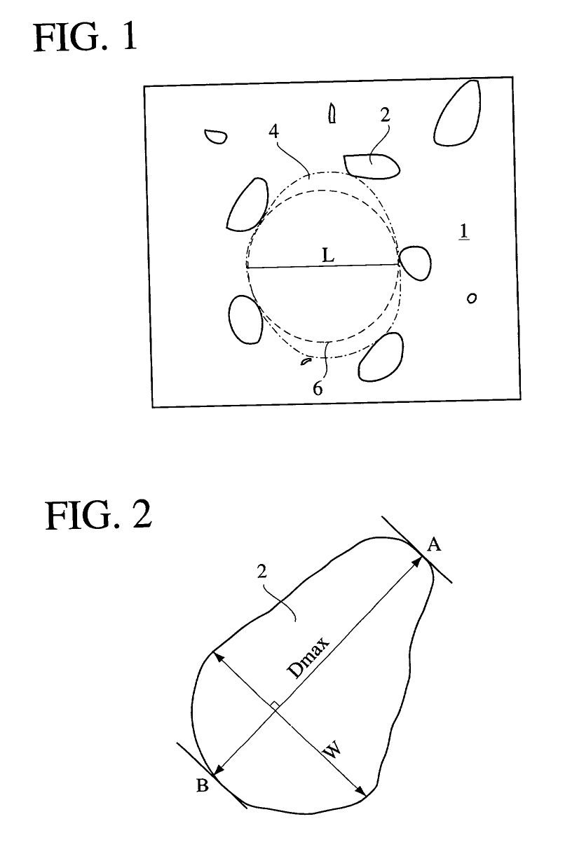

The first target material, as schematically shown in FIG. 1, has a microstructure in which the intermetallic compound 2 is uniformly dispersed in an Al matrix 1.

The maximum diameter of the intermetallic compound 2 is substantially 50 μm or less. The “maximum diameter” referred to herein means the maximum length of the segments connecting any two points on the cross section of the intermetallic compound 2. For example, in the intermetallic compound 2 having an elliptic cross section as shown in FIG. 2, the maximum diameter corresponds to the longest diameter (Dₘₐₓ, length of segment AB). With a uniform dispersion, in the Al matrix, of the intermetallic compound 2 having a maximum diameter Dₘₐₓ of 50 μm or less, the void formation due to cracking of the intermetallic compound is avoided and the increase in splash generation is suppressed even when the overall reduction ratio by plastic working is 50% or more. The maximum diameter Dₘₐₓ is preferably 25 μm or less, more preferably 10 μm or less.

The aspect ratio of the intermetallic compound 2 having a maximum diameter Dₘₐₓ of 0.5 μm or more is 20 or less, preferably 10 or less, and more preferably 5 or less. The “aspect ratio” is represented by Dₘₐₓ/W as shown in FIG. 2, wherein W is the longest diameter perpendicularly intersecting the segment A-B. The void formation which causes the splash generation depends on the size and shape of the intermetallic compound in the microstructure. Therefore, to avoid the splash generation, it is necessary to make the intermetallic compound in the target material as finer as possible and not so flat or long so that the intermetallic compound is not fractured during the production process. By using a rapid solidification powder of the Al alloy described below, the aspect ratio of the intermetallic compound in the target material can be suitably regulated to 20 or less. As a result thereof, the void formation causing the splash generation hardly occurs during the rolling step.

The intermetallic compound 2 is preferred to be dispersed in the Al matrix as uniformly as possible. Specifically, the diameter of the largest inscribed circle in an Al area (pure Al area) containing no intermetallic compound 2 having a maximum diameter Dₘₐₓ of 0.5 μm or more is preferred to be substantially 200 μm or less. The “diameter of the largest inscribed circle” referred to herein is, as schematically shown in FIG. 1, the diameter L of the largest circle 6 sinscribed in the pure Al area 4 surrounded by the intermetallic compounds 2 having a maximum diameter of 0.5 μm or more. When the diameter L of the largest inscribed circle in the pure Al area 4 is larger than 200 μm, the composition of a deposited thin film come to vary to likely cause the hillock formation. The diameter L of the largest inscribed circle in the pure Al area 4 is preferably 50 μm or less, and more preferably 20 μm or less. As defined above, the intermetallic compound having a maximum diameter of less than 0.5 μm is not excluded from being contained in the pure Al area 4. This is because that the intermetallic compound having a maximum diameter of less than 0.5 μm is difficult to be identified under an optical microscope and the presence thereof has little influence on the variation in the composition of the deposited thin films.

[2] Second Target Material

(1) Composition

In a sintered body of a powder of an Al alloy containing the additive element in a relatively large amount, some increase in the area ratio of the compound phase, the maximum diameter and the aspect ratio of the intermetallic compound may be noted. When a sintered body having such a structure is rolled into a large target material, cracking defects are likely to occur in the intermetallic compound phase to cause the splash. Therefore, in the second target material of the present invention, the Al alloy is dispersed in the Al matrix to relieve the deformation stress applied to the intermetallic compound phase by the Al matrix having a low deformation resistance, thereby enabling to produce a large target material containing the additive element in a large amount.

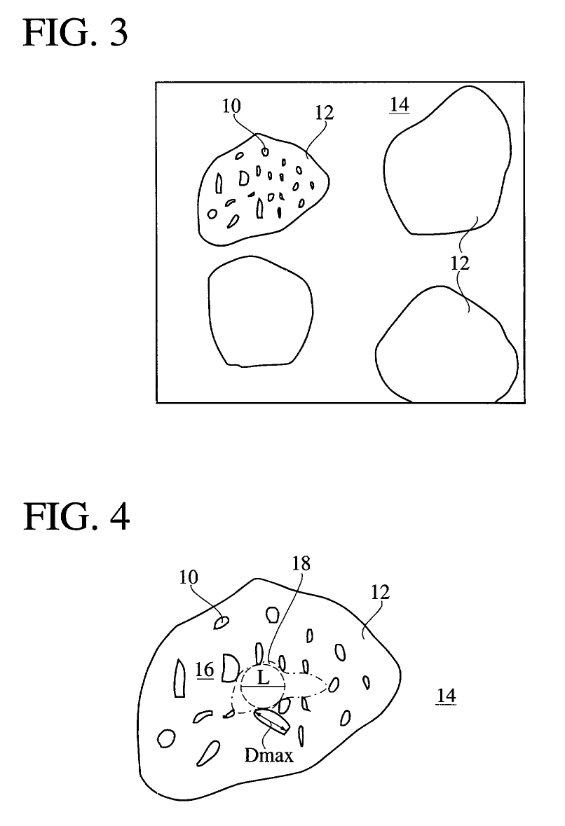

The second target material comprises, as schematically shown in FIG. 3, an Al alloy phase 12 containing intermetallic compounds 10 in a large amount, and a pure Al matrix phase 14. The Al alloy phase 12 contains at least one intermetallic compound-forming element (additive element) which may be the same as used in the first target material. The Al alloy phase 12 comprises 0.1-20 atomic % of the intermetallic compound-forming element and the balance which is preferred to be substantially Al. In particular, when a Group 3A element is contained in an amount exceeding 20 atomic %, the maximum diameter of the intermetallic compound formed in the alloy phase exceeds 50 μm and the aspect ratio is liable to increase. When a sintered body of such a powder is rolled, voids (defects) are likely to be formed therein. Therefore, the content of the additive element in the Al alloy powder for producing the second target material is preferably 20 atomic % or less, and more preferably 0.01-10 atomic %. The content of the additive element based on the whole target material is 0.01-10 atomic %, preferably 0.01-5 atomic %, and more preferably 0.1-2 atomic %. The pure Al phase is preferred to comprise a highly pure Al with a purity of 99.99% or more.

(2) Microstructure

In the dispersion structure of the alloy phase 12 comprising Al alloy having a large deformation resistance in the pure Al matrix phase 14 having a low deformation resistance, the pure Al matrix phase 14 acts as a binder. The pure Al matrix phase 14 having a low deformation resistance relieves the deformation stress applied to the alloy phase 12. As a result thereof, the void formation due to microcracks during plastic working is effectively suppressed, and correspondingly, the splash is also effectively prevented in the second target material having the alloy phase 12 and the pure Al matrix phase 14 as compared with a target material having only one phase.

The Al alloy phase 12 has an eutectic structure in which a relatively large amount of the intermetallic compounds 10 is dispersed. Since the maximum diameter Dₘₐₓ of the intermetallic compound is 50 μm or less, the void formation due to cracking of the intermetallic compound is avoided and the splash is suppressed even when the overall reduction ratio by plastic working is 50% or more. The maximum diameter Dₘₐₓ is preferably 30 μm or less, and more preferably 15 μm or less. The aspect ratio of the intermetallic compound 10 having a maximum diameter of 0.5 μm or more is 20 or less, preferably 15 or less, and more preferably 10 or less. By regulating the aspect ratio of the intermetallic compound in the alloy phase 12 to 20 or less, the void formation causing the splash becomes hard to occur even when subjected to rolling.

As shown in FIG. 4, the intermetallic compound 10 is preferred to be dispersed in the alloy phase 12 as uniformly as possible. Specifically, the diameter L of the largest inscribed circle 18 in a pure Al area 16 containing no intermetallic compound 10 having a maximum diameter Dₘₐₓ of 0.5 μm or more is preferably 100 μm or less, more preferably 50 μm or less, and particularly preferably 10 μm or less.

The maximum diameter of the Al alloy phase 12 is preferred to be substantially 200 μm or less. More preferred is 150 μm or less. By controlling the maximum diameter of the Al alloy phase 12 to substantially 200 μm or less, the intermetallic compound in the Al alloy phase 12 is refined, thereby minimizing the defect due to the deformation stress more effectively.

[3] Sputtering Area

The production of a large LCD requires a target material having a large sputtering area. Therefore, the first and second target materials of the present invention are preferred to have a sputtering area of 0.3 m² or more, particularly when used for forming thin film electrodes of LCD currently coming to be widely used. A target material having a large sputtering area is produced by hot rolling. In the production of the first and second target materials of the present invention, voids due to cracking of the intermetallic compound hardly occur even when the rolling reduction is larger than 50%. Therefore, the present invention is particularly suitable for obtaining a target material having a large sputtering area.

[B] Production Method of Target Material

The first and second target materials may be produced by charging a rapid solidification powder into a can and then pressure-sintering the powder by HIP, hot press, etc.

[1] Production Method of First Target Material

(1) Production of rapid solidification powder of Al alloy

The powder for producing the first target material is produced by rapidly solidifying an Al alloy containing the intermetallic compound-forming element. The rapid solidification powder of the Al alloy may be produced by a gas atomizing process in which a melt of the Al alloy is made into fine powder by spraying the melt into an inert gas atmosphere such as nitrogen, argon, etc.

The use of the rapid solidification method such as a gas atomizing process, etc. (i) prevents the macro segregation of Al found in the conventional casting method, and (ii) provides a target material having a microstructure in which the precipitates of the intermetallic compound are finely dispersed while preventing the growth of a coarse dendritic structure. When sputtering a target material having such a microstructure attained by the use of the rapid solidification powder, thin films of Al alloy with extremely uniform distribution of the alloy composition can be obtained.

The rapid solidification powder of the All alloy has an eutectic structure comprises a matrix phase of Al solid solution and a precipitate phase of intermetallic compound uniformly dispersed in the matrix phase. The dispersed intermetallic compound phase makes the deformation resistance higher than that of a pure Al powder. Since the first target material is produced only from the rapid solidification powder of the Al alloy, the content of the intermetallic compound-forming element in the rapid solidification powder of the Al alloy is needed to be relatively low, and usually 0.01-10 atomic %, preferably 0.01-5 atomic %, more preferably 0.01-1 atomic %. When the content of the intermetallic compound is within the above range, a uniform and fine intermetallic compound phase is formed in a sintered body made only of the rapid solidification powder of the Al alloy, and the intermetallic compound becomes hard to be fractured during hot rolling.

The maximum particle size of the Al alloy powder is substantially 200 μm or less. When the maximum particle size is substantially 200 μm or less, the Al alloy solidifies rapidly to provide a fine powder while preventing the intermetallic compound from growing to flaky form. Therefore, by pressure-sintering the rapid solidification powder of the Al alloy having a maximum particle size of substantially 200 μm or less, the void formation causing the splash can be effectively suppressed in the subsequent hot-rolling step. The maximum particle size of the rapid solidification Al alloy powder is preferably 150 μm or less, and more preferably 100 μm or less. The use of the Al alloy powder produced by the rapid solidification makes the maximum diameter of the intermetallic compound dispersed in the Al matrix substantially 50 μm or less, preferably 25 μm or less, and more preferably 10 μm or less.

As described above, since the rapid solidification Al alloy powder including Al and the intermetallic compound-forming element has a microstructure not attained from a mixture of pure Al and the intermetallic compound-forming element, a target material produced from the rapid solidification Al alloy powder has a microstructure free from voids.

(2) Pressure Sintering

The rapid solidification Al alloy powder is compressed and pressure-sintered by HIP, hot press, etc. HIP is conducted by charging the rapid solidification Al alloy powder into a can made of a metal being relatively soft and heat-resistant, such as pure iron, etc., sealing the can after deaeration, and heating the can under pressure. Hot press is carried out by charging the rapid solidification Al alloy powder into a cavity of a press mold, and heating the powder while compressing the powder by a plunger. In both the methods, the sintering temperature is preferably 400-600° C. When less than 400° C., the powder is insufficiently sintered even under pressure, and Al is detrimentally melted when the sintering temperature exceeds 600° C. The sintering temperature is more preferably 450-550° C.

To obtain a dense sintered body free from voids causing the splash, the sintering pressure is preferably 50 MPa or higher, and more preferably 100-200 MPa. The sintering time is preferably 1 hour or longer under the above temperature and pressure conditions.

The number of defects (number of voids having a longer diameter of 1 μm or more, and measured by a dye penetrant test) in a non-rolled target material is usually 10 or less per mm².

(3) Hot Rolling

To make the structure of the sintered body more uniform and make the sputtering area of the target material wider, in particular, 0.3 m² or more, the sintered body is preferred to be hot-rolled. The hot-rolling temperature is preferred to be substantially equal to or above the recrystallization temperature of Al, and up to a temperature which does not create a local rise in temperature exceeding the melting point of Al during the rolling process.

Specifically, the rolling temperature is preferably 400-600° C., and more preferably 400-550° C.

The rolling reduction is preferably 80% or less. When a rolling reduction of 50% or more is intended, the fracture of the intermetallic compound during the rolling process can be minimized by employing a relatively high rolling temperature within 400-600° C. The number of defects (number of voids having a longer diameter of 1 μm or more, and measured by a dye penetrant test) in a rolled target material thus obtained is usually 10 or less per mm², preferably 5 or less per mm².

[2] Production Method of Second Target Material

(1) Production of Rapid Solidification Powder

(a) Powder of Al Alloy

The rapid solidification Al alloy powder for producing the second target material may be the same as used in producing the first target material except that the content of the intermetallic compound-forming element in the Al alloy powder is higher than the final content in a resulting target material, because the Al alloy powder is mixed with the pure Al powder. The use of the Al alloy powder made by the rapid solidification makes the maximum diameter of the intermetallic compound dispersed in the alloy phase substantially 50 μm or less, preferably 30 μm or less, and more preferably 15 μm or less.

Since the maximum particle size of the Al alloy powder is substantially 200 μm or less, the maximum diameter of the alloy phase is also substantially 200 μm or less. There appears to be a correlation between the size of the intermetallic compound in the alloy powder and the particle size of the alloy powder. It has been found that the precipitates of the intermetallic compound become finer when the particle size of the Al alloy powder is substantially 200 μm or less, and the defects formation due to the deforming pressure during the rolling process can be prevented in a sintered body made of such an Al alloy powder. The maximum particle size of the Al alloy powder is preferably 150 μm or less, and more preferably 100 μm or less.

(b) Powder of Pure Al

The powder of pure Al comprises a high purity Al with a purity of 99.99% or more, and may be produced, like the Al alloy powder, by a gas atomizing method. The maximum particle size of the pure Al powder is preferred to be substantially 200 μm or less. When the maximum particle size is larger than 200 μm, a homogeneous mixture of the pure Al powder with the Al alloy powder is not obtained. The maximum particle size is more preferably 150 μm or less, and particularly preferably 100 μm or less.

(2) Mixing of Rapid Solidification Powders

An Al alloy powder containing a relatively large amount of the additive element correspondingly has a large deformation resistance. Therefore, voids are formed in a sintered body even when produced by HIP, hot press, etc., and also the fracture of the intermetallic compound is likely to occur during the hot rolling process.

In the second target material of the present invention, the above problem has been eliminated by using a uniform powder mixture of the Al alloy powder with the pure Al powder having a low deformation resistance. In a sintered body of such a powder mixture, since the Al alloy phase is dispersed in the Al matrix and the deformation stress applied to the intermetallic compound during the rolling is relieved by the Al matrix having a low deformation resistance, a large target material with a high concentration of the additive element can be obtained. When the Al alloy powder contains a large amount of the additive element, the pure Al powder is added to the Al alloy powder in an amount (i) sufficient for relieving the high deformation resistance of the Al alloy powder, and (ii) not making the structure of the thin films formed by the sputtering non-uniform.

(3) Pressure Sintering

By pressure-sintering the mixture of the rapid solidification powders, a target material with little sintering defects can be obtained. The pressure sintering is conducted under the same conditions as in the production of the first target material.

(4) Hot Rolling

The pure Al phase surrounding the Al alloy phase prevents excessive stress form being applied to the Al alloy phase during hot-rolling a sintered body of the mixture of the rapid solidification powders. Therefore, the void formation due to the fracture of the intermetallic compound can be minimized. The conditions for the hot rolling are the same as in the production of the first target material.

The present invention will be further described while referring to the following Examples which should be considered to illustrate various preferred embodiments of the present invention.

### EXAMPLES 1-10

Each Al alloy having a composition shown in Table 1 was gas-atomized in nitrogen atmosphere and classified into a powder having a maximum particle size of 60 μm. The powder was charged into a soft iron can of 133 mm in inner diameter, 15 mm in height and 2 mm in thickness. The can was degassed under heating while evacuating the can to a pressure of 10⁻³ Pa or lower. Then, the powder was pressure-sintered by HIP (hot isostatic press) under a pressure of 127 MPa at 550° C. for 3 hours. Then the soft iron can was removed by machining to obtain each sintered, non-rolled, single-phase target material of 100 mm in diameter and 4 mm in thickness.

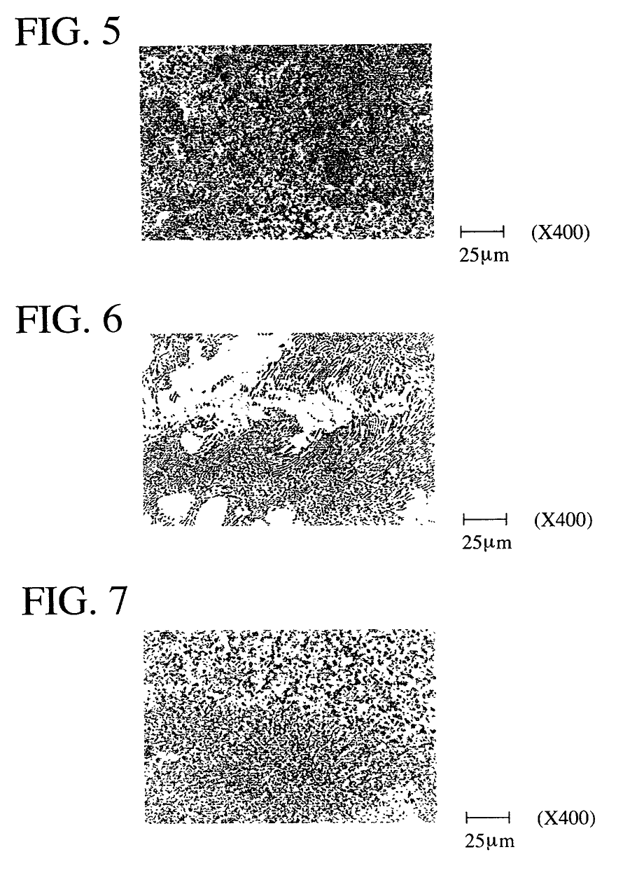

The microstructure of each target material thus obtained was observed under an optical microscope (×400) to measure the maximum diameter and the maximum aspect ratio (maximum value of longer diameter/shorter diameter) of the intermetallic compound in the microstructure, and the diameter of the largest inscribed circle in the pure Al area (diameter of the largest inscribed circle in the Al area containing no intermetallic compound having a maximum diameter of 0.5 μm or more). The number of defects, i.e., the number of voids having a longer diameter of 1 μm or more was counted with respect to the mirror-polished surface of each target material by a dye penetrant test to obtain the number of defects per mm². The results are shown in Table 1. Also, FIG. 5 is a photomicrograph by an optical microscope (×400) showing the microstructure of the target material having a composition of Al-2 atomic % Nd produced in Example 10.

### COMPARATIVE EXAMPLES 1-3

Each Al alloy melt having a composition shown in Table 1 was cast in a mold having a cylindrical cavity of 150 mm in diameter and 100 mm in height. The cast product was machined to obtain each cast, non-rolled, single-phase target material of 100 mm in diameter and 4 mm in thickness.

The maximum diameter and the maximum aspect ratio of the intermetallic compound in the microstructure of the target material, the diameter of the largest inscribed circle in the pure Al area, and the number of defects in the microstructure were measured in the same manner as in Example 1. The results are shown in Table 1. FIG. 6 is a photomicrograph by an optical microscope (×400) showing the microstructure of the target material of Comparative Example 3.

Each target material of Examples 1-10 and Comparative Examples 1-3 was sputtered in a DC magnetron sputtering system under an argon pressure of 0.3 Pa and a supplied power of 0.5 kW to form thin films on a 4-inch square Si wafer. Ten thin films each having a thickness of 200 nm were formed for each piece of target material. The protuberances with a size (longer diameter) of 5 μm or more found on the thin films of the Al alloy were regarded as the splash, and the average number of the splash per substrate was calculated. The results are shown in Table 1.

TABLE 1

| | Composition of Powder | | HIP-Sintering Conditions | | | |
|---|---|---|---|---|---|---|
| | (atomic %) | | Temperature | Time | Pressure | Composition |
| No. | Alloy Powder | Pure Al Powder | (° C.) | (h) | (MPa) | (atomic %) |
| Examples | | | | | | |
| 1 | Al-0.5Ti | none | 550 | 3 | 127 | Al-0.5Ti |
| 2 | Al-1.0Ti | none | 550 | 3 | 127 | Al-1.0Ti |
| 3 | Al-2.0Ti | none | 550 | 3 | 127 | Al-2.0Ti |
| 4 | Al-0.5Ti-0.5Ta | none | 550 | 3 | 127 | Al-.5Ti-0.5Ta |
| 5 | Al-1.0Ce | none | 550 | 3 | 127 | Al-1.0Ce |
| 6 | Al-1.0Ce-1.0Cu | none | 550 | 3 | 127 | Al-1.0Ce-1.0Cu |
| 7 | Al-1.0Ce-1.0Zr | none | 550 | 3 | 127 | Al-1.0Ce-1.0Zr |
| 8 | Al-0.5Nd | none | 550 | 3 | 127 | Al-0.5Nd |
| 9 | Al-1.0Nd | none | 550 | 3 | 127 | Al-1.0Nd |
| 10 | Al-2.0Nd | none | 550 | 3 | 127 | Al-2.0Nd |
| Comparative | | | | | | |
| Examples | | | | | | |
| 1 | Al-1.0Ti* | none | — | — | — | Al-1.0Ti |
| 2 | Al-0.5Ti-0.5Ta* | none | — | — | — | Al-0.5Ti-0.5Ta |
| 3 | Al-2.0Nd* | none | — | — | — | Al-2.0Nd |

| | | | Diameter of | | |
|---|---|---|---|---|---|
| | | | Largest | | Thin Films |
| | Maximum | Maximum | Inscribed | | Numbers of |
| | Diameter | Aspect ratio | Circle in Al | Numbers of | Splash |
| | Compound | of | Area | Defects | per |
| No. | (mm) | Compound | (mm) | per mm² | substate |
| Examples | | | | | |
| 1 | 3 | 1.8 | 40 | 2 | 0.1 |
| 2 | 5 | 1.5 | 25 | 5 | 0.5 |
| 3 | 10 | 1.7 | 15 | 4 | 0.2 |
| 4 | 4.5 | 1.4 | 23 | 6 | 0.8 |
| 5 | 2 | 1.3 | 7 | 4 | 0.7 |
| 6 | 3.5 | 1.8 | 5 | 3 | 0.5 |
| 7 | 4.5 | 1.4 | 4.5 | 4 | 0.7 |
| 8 | 1 | 1.5 | 10 | 3 | 0.5 |
| 9 | 2 | 2 | 7 | 2 | 0.2 |
| 10 | 5 | 1.5 | 4 | 2 | 0.3 |
| Comparative | | | | | |
| Examples | | | | | |
| 1 | 25 | 22 | 25 | 15 | 2 |
| 2 | 30 | 30 | 30 | 18 | 5 |
| 3 | 30 | 19 | 30 | 22 | 4 |

As seen from Table 1 and FIGS. 5 and 6, the sintered, non-rolled, single-phase target materials of Examples 1-10 had a microstructure in which fine intermetallic compounds were uniformly dispersed. On the other hand, the cast, non-rolled, single-phase target materials of Comparative Examples 1-3 had a large aspect ratio of the intermetallic compound, showing that the intermetallic compound was flat in its shape, and had a large pure Al area containing no intermetallic compound having a maximum diameter of 0.5 μm or more. The number of defects measured by a dye penetrant test showed a tendency to extremely increase in the cast, non-rolled, single-phase target materials as compared with the sintered, non-rolled, single-phase target materials. Also, the thin films of Comparative Examples 1-3 had an increased number of the splash corresponding to an increased number of defects in the cast, non-rolled, single-phase target materials.

### EXAMPLES 11-20

Each Al alloy having a composition shown in Table 2 was made into a rapid solidification powder by a gas atomizing method in nitrogen atmosphere and classified into a powder having a maximum particle size of 60 μm. The powder was charged into a soft iron can having an internal volume of 330 mm×530 mm×50 mm and a thickness of 2 mm. The can was degassed under heating while evacuating the can to a pressure of 10⁻³ Pa or lower. The powder was subjected to HIP under a pressure of 127 MPa at 550° C. for 3 hours, and then hot-rolling at a temperature and a rolling reduction shown in Table 2. Then the soft iron can was removed by machining to obtain each sintered, rolled, single-phase target material having a size of 550 mm×690 mm×6 mm.

The maximum diameter and the maximum aspect ratio of the intermetallic compound in the microstructure of the target material, the diameter of the largest inscribed circle in the pure Al area, and the number of defects in the microstructure were measured in the same manner as in Example 1. The results are shown in Table 2. Also, FIG. 7 is a photomicrograph by an optical microscope (×400) showing the microstructure of the target material having a composition of Al-2 atomic % Nd produced in Example 20.

### COMPARATIVE EXAMPLES 4-7

Each additive element powder of Table 2 having a maximum particle size of 35 μm was blended with a pure Al powder having a maximum particle size of 60 μm in a rocking mixer to prepare each powder mixture having a composition shown in Table 2. In the same manner as in Example 1, the powder mixture was charged into a soft iron can having an internal volume of 330 mm×530 mm×50 mm and a thickness of 2 mm, and after degassing, successively subjected to HIP, hot rolling and machining to obtain each sintered, rolled, single-phase target material having a size of 550 mm×690 mm×6 mm.

The maximum diameter and the maximum aspect ratio of the intermetallic compound in the microstructure of the target material, the diameter of the largest inscribed circle in the pure Al area, and the number of defects in the microstructure were measured in the same manner as in Example 1. The results are shown in Table 2.

### COMPARATIVE EXAMPLES 8-10

Each Al alloy melt having a composition shown in Table 2 was cast in an iron mold having a cavity of 400 mm×600 mm×50 mm, and the cast product was hot-rolled at a temperature and a rolling reduction shown in Table 2. The rolled product was machined to obtain each cast, rolled, single-phase target material.

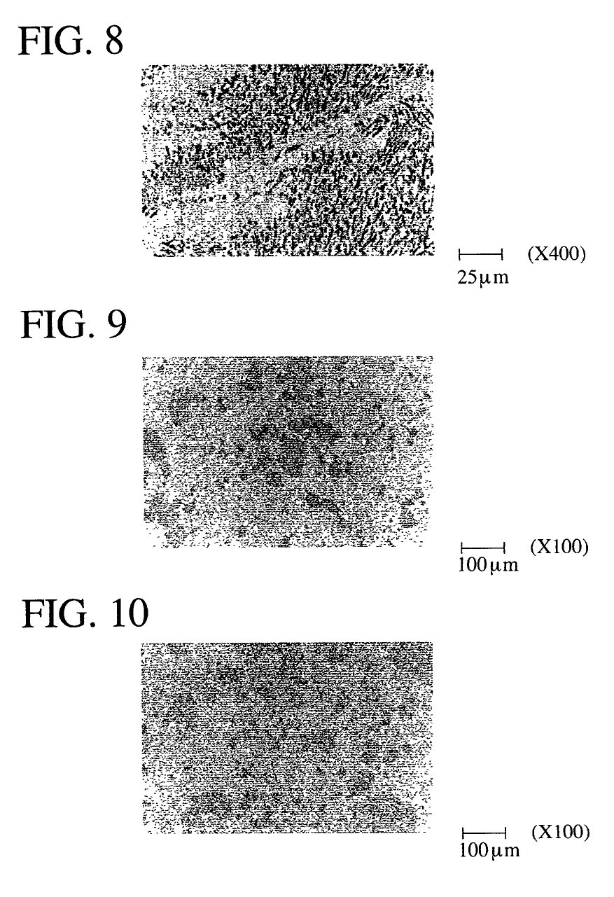

The maximum diameter and the maximum aspect ratio of the intermetallic compound in the microstructure of the target material, the diameter of the largest inscribed circle in the pure Al area, and the number of defects in the microstructure were measured in the same manner as in Example 1. The results are shown in Table 2. FIG. 8 is a photomicrograph by an optical microscope (×400) showing the microstructure of the target material of Comparative Example 10.

Each target material of Examples 11-20 and Comparative Examples 4-10 was sputtered in a DC magnetron sputtering system under an argon pressure of 0.3 Pa and a supplied power of 11 kW to form thin films on a glass substrate having a size of 370 mm×470 mm×1.1 mm. Ten thin films each having a thickness of 200 nm were formed for each piece of target material. The protuberances with a size (longer diameter) of 5 μm or more found on the thin films of the Al alloy were regarded as the splash, and the average number of the splash per substrate was calculated. The results are shown in Table 2.

TABLE 2

| Composition of Powder | | Rolling Conditions | |
|---|---|---|---|
| (atomic %) | HIP-Sintering Conditions | | Rolling |

| | | | | | |
|---|---|---|---|---|---|
| Pure | Temperature | Time | Pressure | Temperature | Reduction |

| | | | | | | | |
|---|---|---|---|---|---|---|---|
| No. | Alloy Powder | Al Powder | (° C.) | (h) | (MPa) | (° C.) | (%) |

Examples

| | | | | | | | |
|---|---|---|---|---|---|---|---|
| 11 | Al-0.5Ta | none | 550 | 3 | 127 | 550 | 63 |
| 12 | Al-1.0Ta | none | 550 | 3 | 127 | 550 | 65 |
| 13 | Al-2.0Ta | none | 550 | 3 | 127 | 550 | 64 |
| 14 | Al-0.5Zr-0.5W | none | 550 | 3 | 127 | 550 | 67 |
| 15 | Al-1.0Y | none | 550 | 3 | 127 | 550 | 62 |
| 16 | Al-1.0Y-1.0Ni | none | 550 | 3 | 127 | 550 | 60 |
| 17 | Al-1.0Y-1.0Zr | none | 550 | 3 | 127 | 550 | 67 |
| 18 | Al-0.5Nd | none | 550 | 3 | 127 | 550 | 65 |
| 19 | Al-1.0Nd | none | 550 | 3 | 127 | 550 | 64 |
| 20 | Al-2.0Nd | none | 550 | 3 | 127 | 550 | 67 |

Comparative Examples

| | | | | | | | |
|---|---|---|---|---|---|---|---|
| 4 | W | added | 550 | 3 | 127 | 550 | 67 |
| 5 | Zr,W | added | 550 | 3 | 127 | 550 | 66 |
| 6 | Y,Ni | added | 550 | 3 | 127 | 550 | 64 |
| 7 | Y | added | 550 | 3 | 127 | 550 | 62 |
| 8 | Al-1.0Y* | none | — | — | — | 550 | 71 |
| 9 | Al-0.5Zr-0.5W* | none | — | — | — | 550 | 64 |
| 10 | Al-2.0Nd* | none | — | — | — | 550 | 62 |

Note: “*” is a composition of the alloy melt for casting.

Target

| | | | | | | |
|---|---|---|---|---|---|---|
| | | | | Diameter of | | |
| | | | | Largest | | Thin Films |
| | | Maximum | Maximum | Inscribed | | Number of |
| | | Diameter of | Aspect ratio | Circle in Al | Number of | Splash |
| | Composition | Compound | of | Area | Defects | per |
| No. | (atomic %) | (mm) | Compound | (mm) | per mm² | substrate |

Examples

| | | | | | | |
|---|---|---|---|---|---|---|
| 11 | Al-0.5Ta | 5 | 1.8 | 25 | 3 | 0.1 |
| 12 | Al-1.0Ta | 5 | 1.5 | 20 | 4 | 0.3 |
| 13 | Al-2.0Ta | 10 | 1.7 | 15 | 2 | 0.2 |
| 14 | Al-0.5Zr-0.5W | 4.5 | 1.4 | 23 | 3 | 0.2 |
| 15 | Al-1.0Y | 2 | 1.3 | 7 | 2 | 0.2 |
| 16 | Al-1.0Y-1.0Ni | 3.5 | 1.8 | 5 | 3 | 0.4 |
| 17 | Al-1.0Y-1.0Zr | 4.5 | 1.4 | 4.5 | 2 | 0.2 |
| 18 | Al-0.5Nd | 1 | 1.5 | 10 | 2 | 0.1 |
| 19 | Al-1.0Nd | 2 | 2 | 7 | 3 | 0.2 |
| 20 | Al-2.0Nd | 5 | 1.5 | 4 | 3 | 0.4 |

Comparative Examples

| | | | | | | |
|---|---|---|---|---|---|---|
| 4 | Al-3W | 55 | 1.7 | 25 | 60 | 6 |
| 5 | Al-0.5Zr-0.5W | 50 | 1.4 | 30 | 65 | 5 |
| 6 | Al-1.0Y-1.0Ni | 65 | 1.6 | 50 | 55 | 2.1 |
| 7 | Al-1.0Y | 70 | 1.7 | 70 | 45 | 1.3 |
| 8 | Al-1.0Y | 25 | 25 | 20 | 25 | 2 |
| 9 | Al-0.5Zr-0.5W | 30 | 35 | 25 | 30 | 4 |
| 10 | Al-2.0Nd | 30 | 30 | 20 | 35 | 4.2 |

As seen from Table 2 and FIGS. 7 and 8, the sintered, rolled, single-phase target materials of Examples 11-20 had a microstructure in which fine intermetallic compounds were uniformly dispersed. On the other hand, the sintered, rolled, single-phase target materials produced from the mixture of the additive element powder and the pure Al powder in Comparative Examples 4-7 had a microstructure having coarse intermetallic compounds. Therefore, the target materials of Comparative Examples 4-7 had a great number of voids. Although the cast, rolled, single-phase target materials of Comparative Examples 8-10 had a microstructure finer than that of the sintered, rolled, single-phase target materials of Comparative Examples 4-7, the target materials of Comparative Examples 8-10 had a large aspect ratio of the intermetallic compound and a large pure Al area containing no intermetallic compound having a maximum diameter of 0.5 μm or more. Also, the target materials of Comparative Examples 8-10 had an increased number of defects as compared with Examples 11-20. This is attributable to the voids formation due to the fracture of the intermetallic compound having a large aspect ratio.

Also, the thin films of Comparative Examples had an increased number of the splash corresponding to an increased number of defects in the sintered, rolled, single-phase target materials of Comparative Examples 4-7 and the cast, rolled, single-phase target materials of Comparative Examples 8-10.

### EXAMPLES 21-25

Each Al alloy having a composition shown in Table 3 and a pure Al were made into rapid solidification powders by a gas atomizing method in nitrogen atmosphere and classified into a respective powder having a particle size of 150 μm or less. The Al alloy powder and the pure Al powder thus obtained were blended in a rocking mixer so as to have a final composition of the target material as shown in Table 3. The powder mixture was charged into a soft iron can having an internal volume of 133 mm (inner diameter)×10 mm and a thickness of 2 mm. After degassing the can at 400° C. for 3 hours while evacuating the can to a pressure of 10⁻³ Pa or lower, the can was sealed. Then, the powder was subjected to HIP under a pressure of 127 MPa for 3 hours at a temperature shown in Table 3. After removing the can, the sintered powder was machined into a disc shape of 100 mm (diameter)×4 mm to obtain each sintered, non-rolled, composite-phase target material having a composite structure consisting of the alloy phase and the Al matrix phase. Further, in the same manner as above except for using only the Al alloy powder, each sintered, non-rolled, single-phase target material was produced (Examples 24 and 25).

The maximum diameter and the maximum aspect ratio of the intermetallic compound in the alloy phase of the target material, and the number of defects (defects having a longer diameter of 1 μm or more) in the whole structure (alloy phase+Al matrix phase) were measured in the same manner as in Example 1. The results are shown in Table 3. Also, FIG. 9 is a photomicrograph by an optical microscope (×100) showing the microstructure of the sintered, non-rolled, composite-phase target material having a composition of Al-2 atomic % Nd produced in Example 21.

Each target material of Examples 21-25 was sputtered in a DC magnetron sputtering system under an argon pressure of 0.3 Pa and a supplied power of 11 kW to form thin films on a glass substrate having a size of 370 mm×470 mm×1.1 mm. Ten thin films each having a thickness of 200 nm were formed for each piece of target material. The protuberances with a size (longer diameter) of 5 μm or more found on the thin films of the Al alloy were regarded as the splash, and the average number of the splash per substrate was calculated. The results are shown in Table 3.

TABLE 3

| | | | | | | Target | | | | |
|---|---|---|---|---|---|---|---|---|---|---|
| | Composition of Powder | | | | | | Maximum | | | Thin Films |
| | (atomic %) | | HIP-Sintering Conditions | | | | Diameter of | Maximum | Number of | Number of |
| | | Pure Al | Temperature | Time | Pressure | Composition | Compound | Aspect ratio | Defects | Splash |
| Example No. | Alloy Powder | Powder | (° C.) | (h) | (MPa) | (atomic %) | (mm) | of Compound | per mm² | per substrate |
| 21 | Al-8Nd | added | 550 | 3 | 127 | Al-2Nd | 12 | 10 | 0 | 0 |
| 22 | Al-6Ni | added | 550 | 3 | 127 | Al-2Ni | 14 | 8 | 0 | 0 |
| 23 | Al-7Cu-7Si | added | 550 | 3 | 127 | Al-1Cu-1Si | 18 | 15 | 0 | 0 |
| 24 | Al-2Ni | none | 550 | 3 | 127 | Al-2Ni | 5 | 3 | 2 | 0.5 |
| 25 | Al-1Cu-1Si | none | 550 | 3 | 127 | Al-1Cu-1Si | 4 | 4 | 1 | 0.7 |

As seen from FIG. 9, practically no void was found in the target materials of Examples 21-25 having a microstructure consisting of the alloy phase (mottled area in the photograph) and the Al matrix phase (gray area in the photograph). In addition, the sintered, non-rolled, composite-phase target materials of Examples 21-23 had a smaller number of the splash as compared with the sintered, non-rolled, single-phase target materials of Examples 24 and 25.

### EXAMPLES 26-30

Each Al alloy having a composition shown in Table 4 and a pure Al were made into rapid solidification powders by a gas atomizing method in nitrogen atmosphere and classified into a respective powder having a particle size of 150 μm or less. The Al alloy powder and the pure Al powder thus obtained were blended in a rocking mixer so as to have a final composition of the target material as shown in Table 4. The powder mixture was charged into a soft iron can having an internal volume of 330 mm×500 mm×50 mm and a thickness of 2 mm. After degassing the can at 400° C. for 3 hours while evacuating the can to a pressure of 10⁻³ Pa or lower, the can was sealed. Then, the powder was subjected to HIP at 550° C. under a pressure of 127 MPa for 3 hours. After removing the can by machining, the sintered product was hot-rolled at a temperature and a rolling reduction shown in Table 4, and machined to obtain each sintered, rolled, composite-phase target material having a size of 550 mm×690 mm×6 mm. In the same manner as above except for using only the Al alloy powder, each sintered, rolled, single-phase target material was produced (Examples 29 and 30).

The maximum diameter and the maximum aspect ratio of the intermetallic compound in the alloy phase of the target material, and the number of defects in the whole structure (alloy phase+Al matrix phase) were measured in the same manner as in Example 21. The results are shown in Table 4. Also, FIG. 10 is a photomicrograph by an optical microscope (×100) showing the microstructure of the target material having a composition of Al-2 atomic % Nd produced in Example 26.

Each target material of Examples 26-30 was sputtered in a DC magnetron sputtering system under an argon pressure of 0.3 Pa and a supplied power of 11 kW to form thin films on a glass substrate having a size of 370 mm×470 mm×1.1 mm. Ten thin films each having a thickness of 200 nm were formed for each piece of target material. The protuberances with a size (longer diameter) of 5 μm or more found on the thin films of the Al alloy were regarded as the splash, and the average number of the splash per substrate was calculated. The results are shown in Table 4.

TABLE 4

| | Composition of Powder | | | | | Rolling Conditions | |
|---|---|---|---|---|---|---|---|
| | (atomic %) | | HIP-Sintering Conditions | | | | Rolling |
| | Alloy | Pure | Temperature | Time | Pressure | Temperature | Reduction |
| Example No. | Powder | Al Powder | (° C.) | (h) | (MPa) | (° C) | (%) |
| 26 | Al-8Nd | added | 550 | 3 | 127 | 550 | 63 |
| 27 | Al-6Ni | added | 550 | 3 | 127 | 550 | 67 |
| 28 | Al-7Cu-7Si | added | 550 | 3 | 127 | 550 | 69 |
| 29 | Al-2Ni | none | 550 | 3 | 127 | 550 | 67 |
| 30 | A1-1Cu-1Si | none | 550 | 3 | 127 | 550 | 62 |

| | Target | | | | |
|---|---|---|---|---|---|
| | | Maximum | | | Thin Films |
| | | Diameter of | Maximum | Number of | Number of |
| | Composition | Compound | Aspect ratio | Defects | Splash |
| Example No. | (atomic %) | (mm) | of Compound | per mm² | per substrate |
| 26 | Al-2Nd | 12 | 10 | 1 | 0 |
| 27 | Al-2Ni | 14 | 8 | 1 | 0 |
| 28 | Al-1Cu-1Si | 18 | 15 | 1 | 0 |
| 29 | Al-2Ni | 4 | 3 | 18 | 0.8 |
| 30 | Al-1Cu-1Si | 5 | 4 | 13 | 0.5 |

As seen from Table 4 and FIG. 10, practically no void was found in the target materials of Examples 26-30 having a microstructure consisting of the alloy phase (mottled area) and the Al matrix phase (gray area). In addition, the sintered, rolled, composite-phase target materials of Examples 26-28 had a smaller number of the splash as compared with the sintered, rolled, single-phase target materials of Examples 29 and 30.

As described above in detail, since the Al-based target material for sputtering of the present invention is produced by pressure-sintering the rapid solidification powder of the Al alloy, the intermetallic compound is finely dispersed in the microstructure and hardly fractured even when subjected to hot rolling. Therefore, the void formation causing the splash can be minimized. Since the Group 3A elements having a high hillock growth resistance is liable to form a flaky intermetallic compound together with Al, the present invention is particularly effective in producing an Al-based target material containing the Group 3A elements.

Since the Al-based target material of the present invention is produced by pressure-sintering a mixture of the Al alloy powder and the pure Al powder, both being produced by a rapid solidification, the intermetallic compound can be refined to minimize the void formation due to the fracture of the intermetallic compound.

By sputtering the target material of the present invention, uniform thin films of the Al alloy can be formed on a large LCD substrate without causing the splash. Therefore, the target material of the present invention is suitable for producing LCD of still larger size to meet the future demands.

What is claimed is:

1. An Al-based target material for sputtering containing at least one intermetallic compound-forming element and an intermetallic compound having a maximum diameter of substantially 50 μm or less.

2. The Al-based target material for sputtering according to claim 1, wherein said Al-based target material has a microstructure in which said intermetallic compound is uniformly dispersed in an Al matrix, said microstructure containing an Al area containing no intermetallic compound having a maximum diameter of 0.5 μm or more, a diameter of the largest circle inscribed in said Al area being 200 μm or less, and aspect ratio of said intermetallic compound being 20 or less.

3. The Al-based target material for sputtering according to claim 2, wherein said Al-based target material comprises 0.01-10 atomic % of said intermetallic compound-forming element and the balance being substantially Al.

4. The Al-based target material for sputtering according to claim 3, wherein the content of said intermetallic compound-forming element is 0.01-5 atomic %.

5. The Al-based target material for sputtering according to claim 2, wherein said Al-based target material is hot-rolled after a pressure sintering process.

6. The Al-based target material for sputtering according to claim 1, wherein said Al-based target material has a sputtering area of 0.3 m² or more.

7. An Al-based target material for sputtering containing at least one intermetallic compound-forming element and having a microstructure comprising an alloy phase containing an intermetallic compound and Al and a matrix phase comprising substantially pure Al, said intermetallic compound in said alloy phase having a maximum diameter of substantially 50 μm or less.

8. The Al-based target material for sputtering according to claim 7, wherein said at least one intermetallic compound-forming element includes a Group 3A element.

9. The Al-based target material for sputtering according to claim 7, wherein said Al-based target material comprises 0.01-10 atomic % of said intermetallic compound-forming element and the balance being substantially Al.

10. The Al-based target material for sputtering according to claim 9, wherein the content of said intermetallic compound-forming element is 0.01-5 atomic %.

11. The Al-based target material for sputtering according to claim 7, wherein a maximum diameter of said alloy phase is substantially 200 μm or less.

12. The Al-based target material for sputtering according to claim 11, wherein said all phase contains an Al area containing no intermetallic compound having a maximum diameter of 0.5 μm or more, a diameter of the largest circle inscribed in said Al area being 100 μm or less, and an aspect ratio of said intermetallic compound being 20 or less.

13. The Al-based target material for sputtering according to claim 7, wherein said Al-based target material is hot-rolled after a pressure sintering process.

14. The Al-based target material for sputtering according to claim 7, wherein said Al-based target material has a sputtering area of 0.3 m² or more.

15. A method of producing an Al-based target material for sputtering, which comprises the steps of preparing an alloy powder by rapidly solidifying an alloy melt comprising 0.01-10 atomic % of an intermetallic compound-forming element and a balance being substantially Al; and pressure-sintering said alloy powder at 400-600° C.

16. The method of producing an Al-based target material for sputtering according to claim 15, wherein the content of said intermetallic compound-forming element in said alloy melt is 0.01-5 atomic %.

17. The method of producing an Al-based target material for sputtering according to claim 16, wherein said intermetallic compound-forming element includes a Group 3A element.

18. The method of producing an Al-based target material for sputtering according to claim 15, wherein said powder of the Al alloy produced by rapid solidification has a maximum diameter of substantially 200 μm or less.

19. The method of producing an Al-based target material for sputtering according to claim 15, wherein said method further comprises a step of hot rolling at 400-600° C. after said pressure sintering.

20. A method producing an Al-based target material for sputtering, which comprises the steps of mixing a rapid solidification powder of an Al alloy comprising an intermetallic compound-forming element and Al with a powder of substantially pure Al; and pressure-sintering the powder mixture at 400-600° C.

21. The method of producing an Al-based target material for sputtering according to claim 20, wherein said intermetallic compound-forming element includes a Group 3A element.

22. The method of producing an Al-based target material for sputtering according to claim 20, wherein the content of said intermetallic compound-forming element is 0.01-10 atomic % based on a total amount of said target material.

23. The method of producing an Al-based target material for sputtering according to claim 22, wherein said rapid solidification powder of the Al alloy comprises 20 atomic % or less of said intermetallic compound-forming element and the balance being substantially Al.

24. The method of producing an Al-based target material for sputtering according to claim 20, wherein said rapid solidification powder of the Al alloy has a maximum diameter of substantially 200 μm or less.

25. The method of producing an Al-based target material for sputtering according to claim 20, wherein said method further comprises a step of hot rolling at 400-600° C. after said pressure sintering.
